(19) United States
(12) Patent Application Publication
(10) Pub. No.: US 2007/0045736 A1
(43) Pub. Date: Mar. 1, 2007

(54) FinFET and method for manufacturing the same

(76) Inventor: Atsushi Yagishita, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/266,357

(22) Filed: Nov. 4, 2005

(30) Foreign Application Priority Data
Jul. 27, 2005 (JP) 2005-217687

(51) Int. Cl. H01L 27/12

(52) U.S. Cl. 257/347

(57) ABSTRACT

A gate electrode is arranged in a direction parallel or perpendicular to a specified crystal orientation of a substrate. A first transistor of a first conductivity type has a first active region, which is arranged in a direction perpendicular to the gate electrode. A second transistor of a second conductivity type has a second active region, which is inclined relative to the gate electrode.

### CROSS-REFERENCE TO RELATED APPLICATIONS

This application is based upon and claims the benefit of priority from prior Japanese Patent Application No. 2005-217687, filed Jul. 27, 2005, the entire contents of which are incorporated herein by reference.

### BACKGROUND OF THE INVENTION

1. Field of the Invention

The present invention relates to complementary metal oxide semiconductor (CMOS) technology using a semiconductor device, such as a Fin-Field Effect Transistor (FinFET) technique, and particularly to a structure formed of transistors of different conductivity types and a method for manufacturing the same.

2. Description of the Related Art

A FinFET, having a three-dimensional structure of a channel region, has been developed. To obtain the performance of the FinFET, the relationship between the direction of a channel region and a surface orientation of silicon is important. It is known that the mobility of electrons and holes varies depending on the surface orientation of silicon crystals. The mobility of electrons is the highest in wafers of the surface orientation (100), while the mobility of holes is the highest in wafers of the surface orientation (110). When a FinFET is formed of a normal wafer of the surface orientation (100) in a direction parallel or perpendicular to the orientation flat (O. F.) or the notch direction (crystal orientation <110>), the surface orientation of the channel surface (Fin side surface) is (110). Therefore, the mobility of a p-channel MOS-FinFET (hereinafter referred to as PMOS-FinFET) is high, but the mobility of an n-channel MOS-FinFET (hereinafter referred to as NMOS-FinFET) is low.

Therefore, a layout, in which only the NMOS-FinFET is inclined by 45 degrees relative to the orientation flat (or the notch direction), is proposed (see, for example, Leland Chang, et al., “Extremely Scaled Silicon Nano-CMOS Devices”, Proceedings of the IEEE, vol. 91, No. 11, November 2003, page 1860). In this layout, since the NMOS-FinFET is shifted by 45 degrees relative to the PMOS-FinFET, there is dead space around the PMOS-FinFET and the NMOS-FinFET. As a result, the layout area is increased. In addition, since the NMOS-FinFET is shifted by 45 degrees, a considerable restriction in design is imposed.

A CMOS-FinFET was invented, in which the channel region of an NMOS-FinFET is formed along the (100) plane and the channel region of a PMOS-FinFET is formed along the (110) plane, and a gate electrode thereof is not perpendicular to the Fin (see for example, US Patent Publication No. 2004/0119100). In this case, it is necessary to set a vertical reference axis, which is inclined by 22.5 degrees relative to the orientation flat, and arrange a gate electrode, a PMOS-FinFET and an NMOS-FinFET with reference to the vertical reference axis.

As described above, the conventional art has problems that it is difficult to lay out the PMOS-FinFET and the NMOS-FinFET optimally in a high density. In addition, since the layout cannot be designed using the conventional MOSFET design property (IP), it must be newly designed.

### BRIEF SUMMARY OF THE INVENTION

According to a first aspect of the invention, there is provided a semiconductor device comprising:

a gate electrode, which is arranged in a direction parallel or perpendicular to a specified crystal orientation of a substrate; a first transistor of a first conductivity type, having a first active region which is arranged in a direction perpendicular to the gate electrode; and a second transistor of a second conductivity type, having a second active region which is inclined relative to the gate electrode.

According to a second aspect of the invention, there is provided a semiconductor device comprising:

a first gate electrode and a second gate electrode, which are arranged in a direction parallel or perpendicular to a specified crystal orientation of a substrate; a first transistor and a second transistor of a first conductivity type, respectively having a first active region and a second active region which are arranged in a direction perpendicular to the first gate electrode and the second gate electrode; and a third transistor and a fourth transistor of a second conductivity type, respectively having a third active region and a fourth active region which are inclined relative to the first gate electrode and the second gate electrode.

According to a third aspect of the present invention, there is provided a method for manufacturing a semiconductor device comprising: forming a first active region which has a side surface arranged in a direction parallel or perpendicular to a specified crystal orientation of a substrate, and a second active region which has a side surface inclined relative to the specified crystal orientation of the substrate; forming a first insulating film which covers the first active region and the second active region; forming a first conductive film on the first insulating film; forming a mask, which is parallel or perpendicular to the specified crystal orientation of the substrate, perpendicular to the first active region, and inclined relative to the second active region; and etching the first conductive film, using the mask, thereby forming a gate electrode.

### BRIEF DESCRIPTION OF THE SEVERAL VIEWS OF THE DRAWING

FIG. 1 is a plan view showing a semiconductor device according to a first embodiment of the present invention;

FIG. 2 is a plan view showing a FinFET as a conventional semiconductor device;

FIG. 3 is a plan view showing a semiconductor device according to a second embodiment of the present invention;

FIGS. 4A and 4B show a third embodiment of the present invention: FIG. 4A is a plan view showing an example of a NAND circuit, and FIG. 4B is a plan view showing an example of a NOR circuit;

FIGS. 5A and 5B show a fourth embodiment of the present invention: FIG. 5A is a plan view showing an example of a NAND circuit, and FIG. 5B is a plan view showing an example of a NOR circuit;

FIGS. 6A and 6B show a fifth embodiment of the present invention: FIG. 6A is a plan view showing an example of a NAND circuit, and FIG. 6B is a plan view showing an example of a NOR circuit;

FIGS. 7A and 7B show a modification of the fifth embodiment of the present invention shown in FIGS. 6A and 6B: FIG. 7A is a plan view showing an example of a NAND circuit, and FIG. 7B is a plan view showing an example of a NOR circuit;

FIGS. 8A and 8B show a sixth embodiment of the present invention modified from the fifth embodiment: FIG. 8A is a plan view showing an example of a NAND circuit, and FIG. 8B is a plan view showing an example of a NOR circuit;

FIGS. 9A and 9B show a seventh embodiment of the present invention modified from the sixth embodiment: FIG. 9A is a plan view showing an example of a NAND circuit, and FIG. 9B is a plan view showing an example of a NOR circuit;

FIGS. 10A and 10B show a case in which the seventh embodiment is applied to FIG. 4: FIG. 10A is a plan view showing an example of a NAND circuit, and FIG. 10B is a plan view showing an example of a NOR circuit;

FIG. 11 is a perspective view showing a step of a method for manufacturing a semiconductor device according to an eighth embodiment, in which the regions indicated by the broken lines A1 and A2 in FIG. 1 are shown;

FIG. 12 is a perspective view showing a manufacturing step subsequent to that shown in FIG. 11;

FIG. 13 is a perspective view showing a manufacturing step subsequent to that shown in FIG. 12;

FIG. 14 is a perspective view showing a manufacturing step subsequent to that shown in FIG. 13;

FIG. 15 is a perspective view showing a manufacturing step subsequent to that shown in FIG. 14;

FIG. 16 is a perspective view showing a manufacturing step subsequent to that shown in FIG. 15;

FIG. 17 is a perspective view showing a manufacturing step subsequent to that shown in FIG. 16;

FIG. 18 is a perspective view showing a manufacturing step subsequent to that shown in FIG. 17;

FIG. 19 is a perspective view showing a manufacturing step subsequent to that shown in FIG. 18;

FIG. 20 is a perspective view showing a step of a method for manufacturing a semiconductor device according to a ninth embodiment, in which the region indicated by the broken line B in FIG. 8B is shown;

FIG. 21 is a perspective view showing a manufacturing step subsequent to that shown in FIG. 20;

FIG. 22 is a perspective view showing a manufacturing step subsequent to that shown in FIG. 21;

FIG. 23 is a perspective view showing a manufacturing step subsequent to that shown in FIG. 22;

FIG. 24 is a perspective view showing a manufacturing step subsequent to that shown in FIG. 23;

FIG. 25 is a perspective view showing a manufacturing step subsequent to that shown in FIG. 24;

FIG. 26 is a perspective view showing a manufacturing step subsequent to that shown in FIG. 25;

FIG. 27 is a perspective view showing a manufacturing step subsequent to that shown in FIG. 24, in which the region indicated by the broken line C in FIG. 8B is shown;

FIG. 28 is a perspective view showing a manufacturing step subsequent to that shown in FIG. 27; and

FIGS. 29A and 29B show a tenth embodiment: FIG. 29A is a plan view showing a semiconductor device, and FIG. 29B is a perspective view showing the region D in FIG. 29A.

### DETAILED DESCRIPTION OF THE INVENTION

Embodiments of the present invention will be described with reference to the accompanying drawings.

### First Embodiment

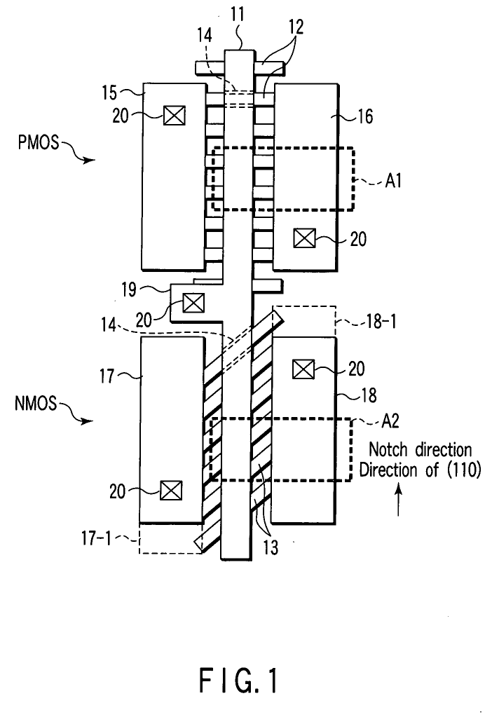

FIG. 1 shows a first embodiment, an example of a CMOS inverter using a FinFET.

Referring to FIG. 1, a gate electrode 11 is formed along a notch direction ((110) direction) on a substrate (not shown), which is a normal wafer having the surface orientation (100). A plurality of Fins 12, which are active regions of a PMOS-FinFET and serve as channel regions, are formed perpendicular to the gate electrode 11. Therefore, the side surfaces of the Fins 12 extend along a (110) plane. A plurality of Fins 13, which are active regions of an NMOS-FinFET and serve as channel regions, are inclined relative to the gate electrode 11. More specifically, the Fins 13 are inclined by about 45 degrees relative to the gate electrode 11. Therefore, the side surfaces of the Fins 13 extend along the (100) plane. The angle of the Fins 13 with respect to the gate electrode 11 may be 45±10 degrees, in which case a desired effect can be obtained.

A gate insulation film 14, indicated by broken lines, is formed between each of the Fins 12 and 13 and the gate electrode 11. The gate insulation film 14 is formed on a side surface of each of the Fins 12 and 13 under the gate electrode 11. The Fins 12 and 13 protrude from the surface of the substrate, for example, at right angles. First ends of the Fins 12 of the PMOS-FinFET, for example, ones of the source and drain regions, are connected by an element region (connecting portion) 15. Second ends of the Fins 12, for example, the others of the source and drain regions, are connected by an element region 16. Further, first ends of the Fins 13 of the PMOS-FinFET, for example, ones of the source and drain regions, are connected by an element region 17. Second ends of the Fins 13, for example, the others of the source and drain regions, are connected by an element region 18. A contact 20 is formed in each of the element regions 15, 16, 17 and 18, and a wide gate region 19, which is formed in a central portion of the gate electrode 11.

In FIG. 1, not all of the Fins 13 are connected to the element regions 17 and 18. However, as indicated by the broken lines 17-1 and 18-1, the element regions 17 and 18 may be extended so far as the layout permits, so that all of the Fins can be connected to the element regions 17 and 18.

The angle formed between the gate electrode 11 and the Fins 13 is not limited to 45 degrees. For example, it may be 135 degrees, 225 degrees or 315 degrees, in which case also the same effect can be obtained.

According to the first embodiment described above, the Fins 12 of the PMOS-FinFET are perpendicular to the gate electrode 11, which is parallel (or perpendicular) to the surface orientation <110> of the crystals of the substrate, while the Fins 13 of the NMOS-FinFET are inclined by 45 degrees relative to the gate electrode 11. Therefore, the mobility of the holes is high in the PMOS-FinFET and the mobility of the electrons is high in the NMOS-FinFET.

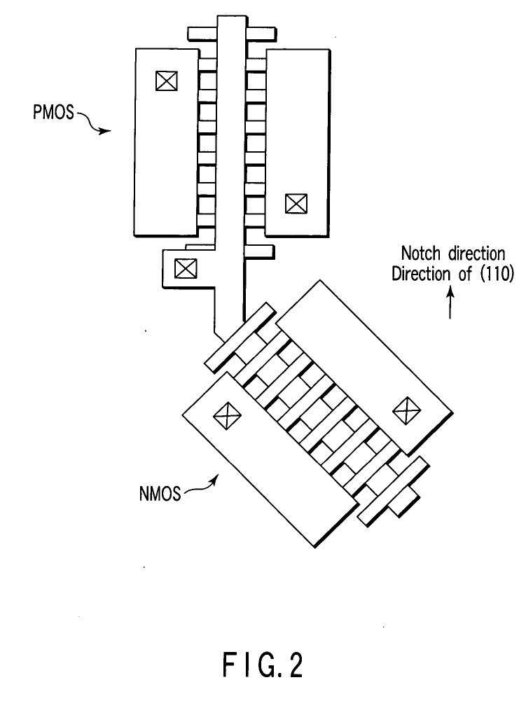

Moreover, the gate electrode 11 is straight, and the Fins 12 of the PMOS-FinFET are perpendicular to the gate electrode, while only the Fins 13 of the NMOS-FinFET are inclined by 45 degrees relative to the gate electrode 11. Therefore, there is no dead space unlike in the case shown in FIG. 2, where the NMOS-FinFET as a whole is shifted by 45 degrees. Consequently, the PMOS-FinFET and the NMOS-FinFET can be laid out easily and the area occupied by the FinFETs in the chip can be small.

The channel length is about 40% increased by inclining the pattern of the Fins 13 of the NMOS-FinFET by 45 degrees relative to the gate electrode 11. However, in the case of NMOS, the mobility on the (100) plane is 100% higher than (twice as high as) that on the (110) plane. Therefore, the merit of the increase in mobility is significant as compared to the demerit of the increase in channel length.

Further, the above semiconductor device has the same layout as that of the conventional FET except for the Fins 12 of the PMOS-FinFET and the Fins 13 of the NMOS-FinFET. There is no restriction in design other than the pattern of the Fins 13 of the NMOS-FinFET. Therefore, the above embodiment is advantageous in that the conventional design property can be utilized.

### Second Embodiment

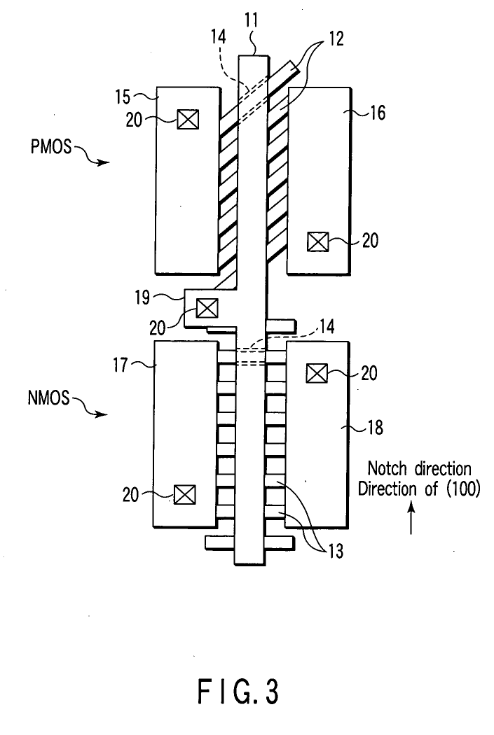

FIG. 3 shows a second embodiment. In the first embodiment, the Fins 13 of the NMOS are inclined relative to the gate electrode 11. In contrast, in the second embodiment, the Fins of the PMOS are inclined relative to the gate electrode 11. The portions of the second embodiment that are the same as those in the first embodiment are identified by the same reference numerals as those used for the first embodiment.

The second embodiment is different from the first embodiment in that the notch or orientation flat of the wafer is shifted by 45 degrees; that is, the notch direction is the direction of (100). As shown in FIG. 3, the gate electrode 11 extends in the notch direction (the direction of (100)). Therefore, the side surfaces of the Fins 12 extend along the (110) plane. The Fins 13 of the NMOS-FinFET are perpendicular to the gate electrode 11. Therefore, the side surfaces of the Fins 13 extend along the (100). The angle of the Fins 12 with respect to the gate electrode 11 may be 45±10 degrees, in which case a desired effect can be obtained.

According to the second embodiment described above, the Fins 12 of the PMOS-FinFET are inclined by 45 degrees relative to the gate electrode 11, which extends along the direction of (100), while the Fins 13 of the NMOS-FinFET are perpendicular to the gate electrode 11. Therefore, the mobility of the holes is high in the PMOS-FinFET and the mobility of the electrons is high in the NMOS-FinFET.

In the second embodiment also, the same effect as in the first embodiment can be obtained.

### Third Embodiment

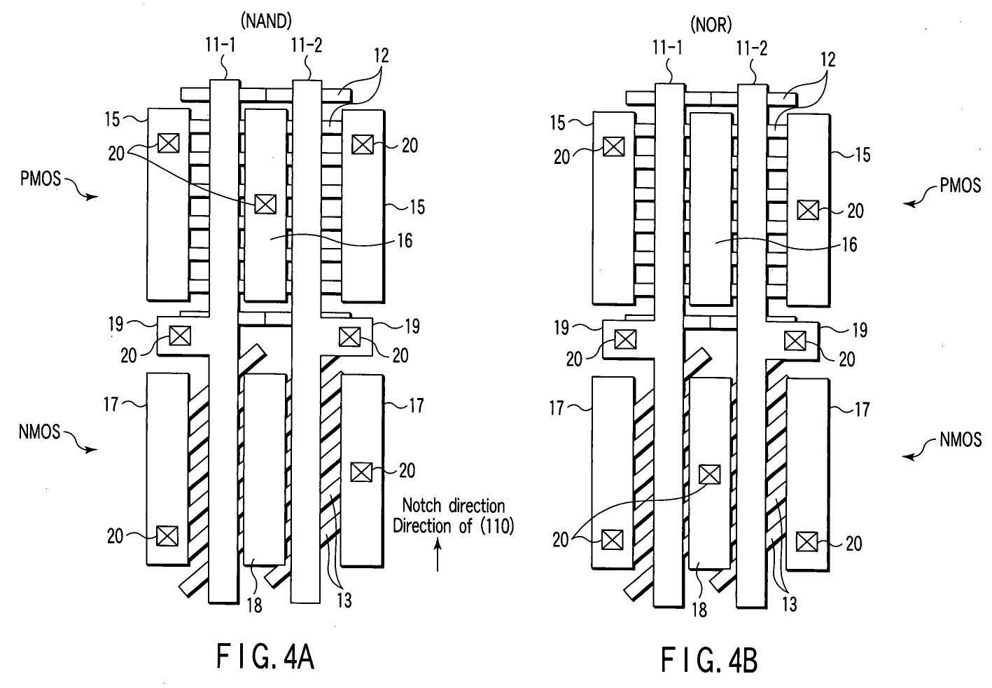

FIGS. 4A and 4B show a third embodiment of the present invention, in which, for example, the structure of the first embodiment is applied to a NAND gate and a NOR gate. FIG. 4A shows an example of a NAND circuit using two CMOS inverter circuits, and FIG. 4B shows an example of a NOR circuit using two CMOS inverter circuits. In FIGS. 4A and 4B, the portions that are the same as those in the first embodiment are identified by the same reference numerals as those used for the first embodiment.

Referring to FIGS. 4A and 4B, gate electrodes 11-1 and 11-2 are arranged along, for example, the notch direction (the direction of (110)). The Fins 12 of the PMOS-FinFET are perpendicular to the gate electrodes 11-1 and 11-2, while the Fins 13 of the NMOS-FinFET are inclined relative to the gate electrodes 11-1 and 11-2. More specifically, the Fins 13 are inclined by, for example, 45 degrees (±10 degrees) relative to the gate electrodes 11-1 and 11-2.

The NAND circuit and the NOR circuit are the same except for the positions of the contacts and an upper metal wire (not shown). In the NAND circuit shown in FIG. 4A, both sources of the PMOS-FinFET are connected to a power source VDD, and a common drain is connected to an output terminal. One of the sources of the NMOS-FinFET is grounded and the other source is connected to the common drain of the PMOS-FinFET as the output terminal. The gate electrodes 11-1 and 11-2 are input terminals.

In the NOR circuit shown in FIG. 4B, one of the sources of the PMOS-FinFET is connected to the power source VDD, and the other source is connected to a common drain of the NMOS-FinFET as an output terminal. Both sources of the NMOS-FinFET are grounded and the common drain is connected to the output terminal. The gate electrodes 11-1 and 11-2 are input terminals.

According to the third embodiment described above, the Fins 12 of the PMOS-FinFET are perpendicular to the gate electrodes 11-1 and 11-2, which are arranged along the direction of (110), while the Fins 13 of the NMOS-FinFET are inclined relative to the gate electrodes 11-1 and 11-2. Therefore, the carrier mobility in both the PMOS-FinFET and the NMOS-FinFET can be increased. Consequently, the NAND circuit and NOR circuit capable of operating at high speed can be obtained.

Moreover, since there is no dead space around the PMOS-FinFET and the NMOS-FinFET, the FinFETs can be laid out efficiently and the area of the chip is prevented from increasing.

It is possible that the gate electrodes 11-1 and 11-2 be arranged along the direction of (100), and the Fins 12 of the PMOS-FinFET be inclined by 45 degrees relative to the gate electrodes 11-1 and 11-2, while the Fins 13 of the NMOS-FinFET be arranged perpendicular to the gate electrodes 11-1 and 11-2, as shown in FIG. 3.

### Fourth Embodiment

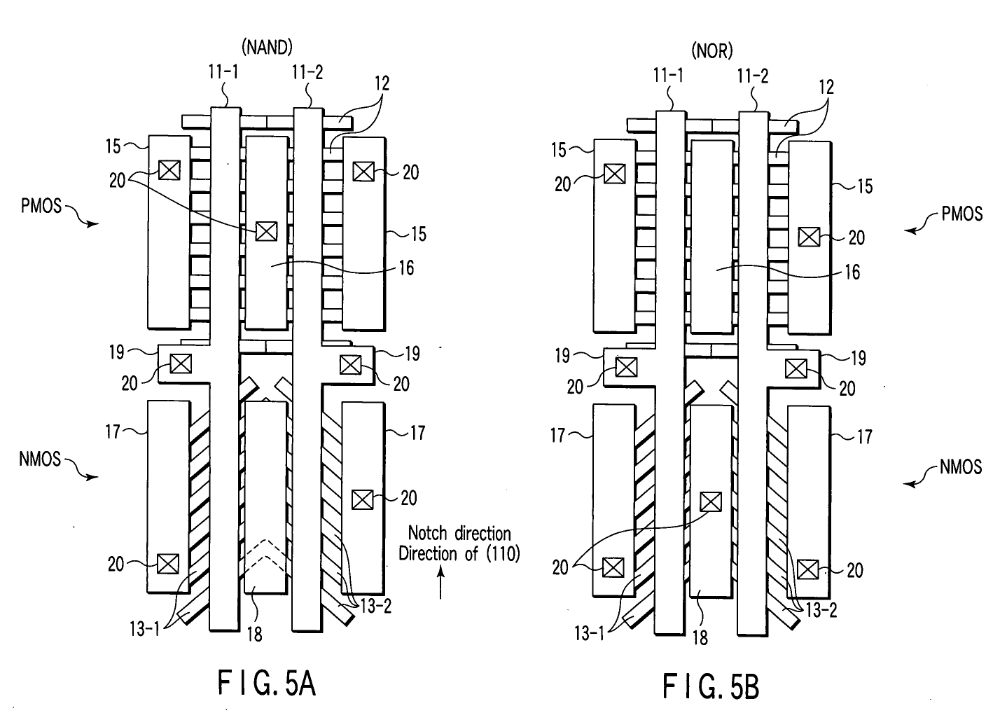

FIGS. 5A and 5B show a fourth embodiment of the present invention, i.e., a modification of the third embodiment. In FIGS. 5A and 5B, the portions that are the same as those in the third embodiment are identified by the same reference numerals as those used for the third embodiment.

Referring to FIGS. 5A and 5B, Fins 13-1 of the NMOS-FinFET are inclined by 45 degrees (±10 degrees) relative to the gate electrode 11-1, and Fins 13-2 are inclined by 315 degrees (±10 degrees) relative to the gate electrode 11-2. In other words, the Fins 13-1 and the Fins 13-2 form the angle of 90 degrees, and the Fins of the NMOS-FinFET and the Fins of the PMOS-Fins form the angle of 45 degrees. The layout of the fourth embodiment is the same as that of the third embodiment except for the Fins 13-1 and 13-2.

In the fourth embodiment also, the same effect as in the third embodiment can be obtained.

It is possible that the gate electrodes 11-1 and 11-2 be arranged along the direction of (100), the Fins 12 of the PMOS-FinFET be inclined by 45 degrees (±10 degrees) relative to the gate electrode 11-1 and by 315 degrees (±10 degrees) relative to the gate electrode 11-2, while the Fins 13-1 and 13-2 of the NMOS-FinFET be arranged perpendicular to the gate electrodes 11-1 and 11-2, as shown in FIG. 3. In this structure also, the carrier mobility in both the PMOS-FinFET and the NMOS-FinFET can be increased.

### Fifth Embodiment

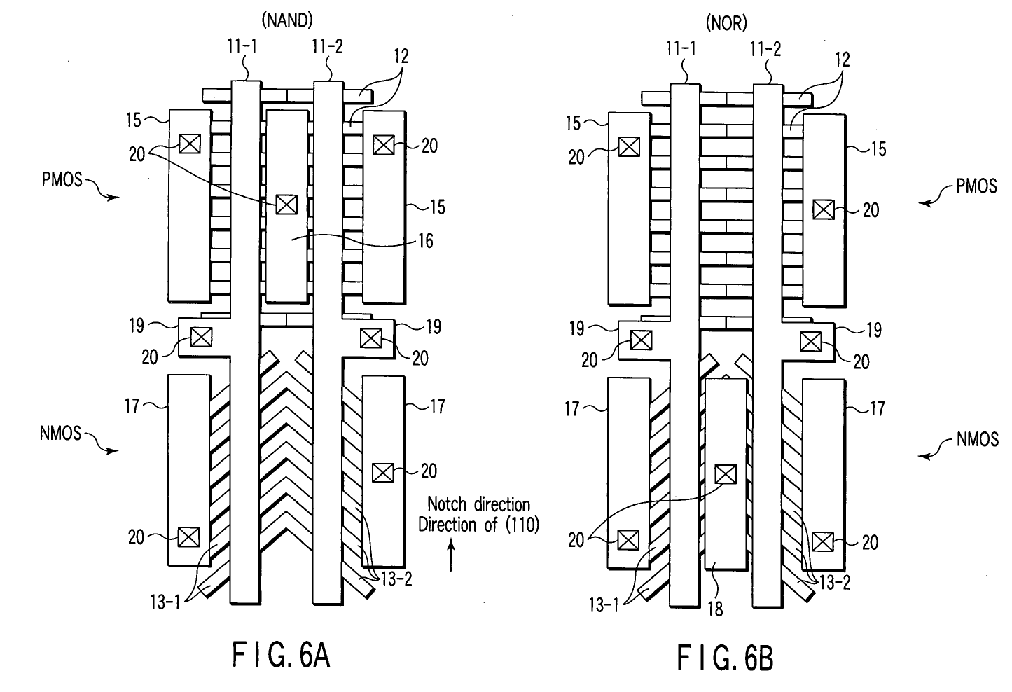

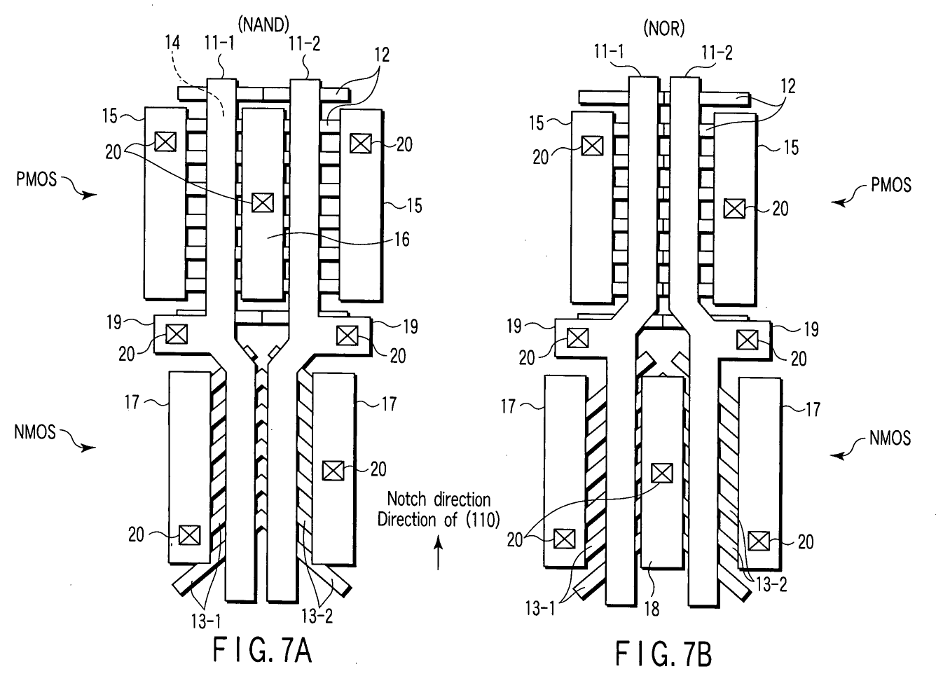

FIGS. 6A and 6B and 7A and 7B show a fifth embodiment of the present invention, i.e., a modification of the fourth embodiment. In the fifth embodiment, the portions that are the same as those in the third embodiment are identified by the same reference numerals as those used for the fourth embodiment.

Referring to FIGS. 6A and 6B, in a region where a contact need not be formed, only Fins are formed in the source/drain regions; that is, a relatively large element region connecting a plurality of source/drain regions is not formed. More specifically, in FIG. 6A, the element region 18 is not formed between the gate electrodes 11-1 and 11-2 of the NMOS-FinFET, and in FIG. 6B, the element region 16 is not formed between the gate electrodes 11-1 and 11-2 of the PMOS-FinFET. Since the Fins 13-1 and Fins 13-2 are arranged perpendicular to each other, the number of Fins that are connected to the contacts 20 at both ends is increased as compared to the case where the Fins are parallel to each other.

In FIGS. 7A and 7B, the distance between the gate electrodes 11-1 and 11-2 is shorter in a portion where a relatively large element region is not formed and only the Fins are formed.

In the fifth embodiment also, the same effect as in the fourth embodiment can be obtained. Moreover, according to the fifth embodiment, the relatively large element region is formed only in the portion where the contacts are required. Thus, since the distance between the gate electrodes 11-1 and 11-2 can be shorter in a portion where no element region is formed, the area occupied by the source/drain regions can be reduced. Therefore, the area occupied by the NAND circuit and the NOR circuit can be reduced.

In addition, if the inverter circuits each having bent gate electrodes are arranged such that the smaller PMOS-FinFET and NMOS-FinFET are staggered, the chip size can be much reduced.

Further, in the structure described above, since the degree of freedom of arrangement of gate electrodes is increased, the margin of forming contacts can be increased.

Furthermore, since the distance between the gate electrodes 11-1 and 11-2 is reduced, the length of the Fins between the gate electrodes 11-1 and 11-2 can be reduced accordingly. Therefore, the parasitic resistance in the source/drain regions can be reduced, and the device operation can be further increased.

### Sixth Embodiment

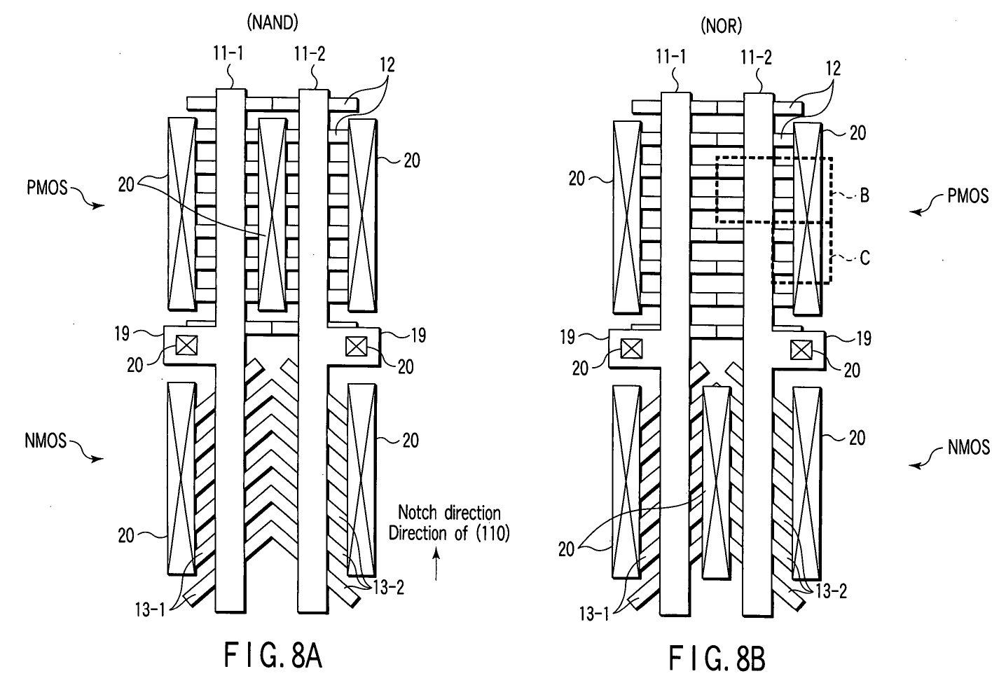

FIGS. 8A and 8B show a sixth embodiment of the present invention, i.e., a modification of the fifth embodiment. In FIGS. 8A and 8B, the portions that are the same as those in the fifth embodiment are identified by the same reference numerals as those used for the fifth embodiment.

Unlike the fifth embodiment, the sixth embodiment does not have element regions 15, 16, 17 and 18 which electrically connect the adjacent Fins. The sixth embodiment is characterized in that the adjacent fins are directly connected by contacts 20, which are slightly smaller than the element regions 15, 16, 17 and 18. The contacts 20 are formed by, for example, filling contact holes (not shown) with a metal material.

In the sixth embodiment also, the same effect as in the fifth embodiment can be obtained. Moreover, in the sixth embodiment, the adjacent Fins are directly connected by the contacts 20 without forming relatively large element regions. Thus, the number of manufacturing steps can be reduced.

In the sixth embodiment, it is possible that the gate electrodes 11-1 and 11-2 have bent configuration as shown in FIGS. 7A and 7B.

### Seventh Embodiment

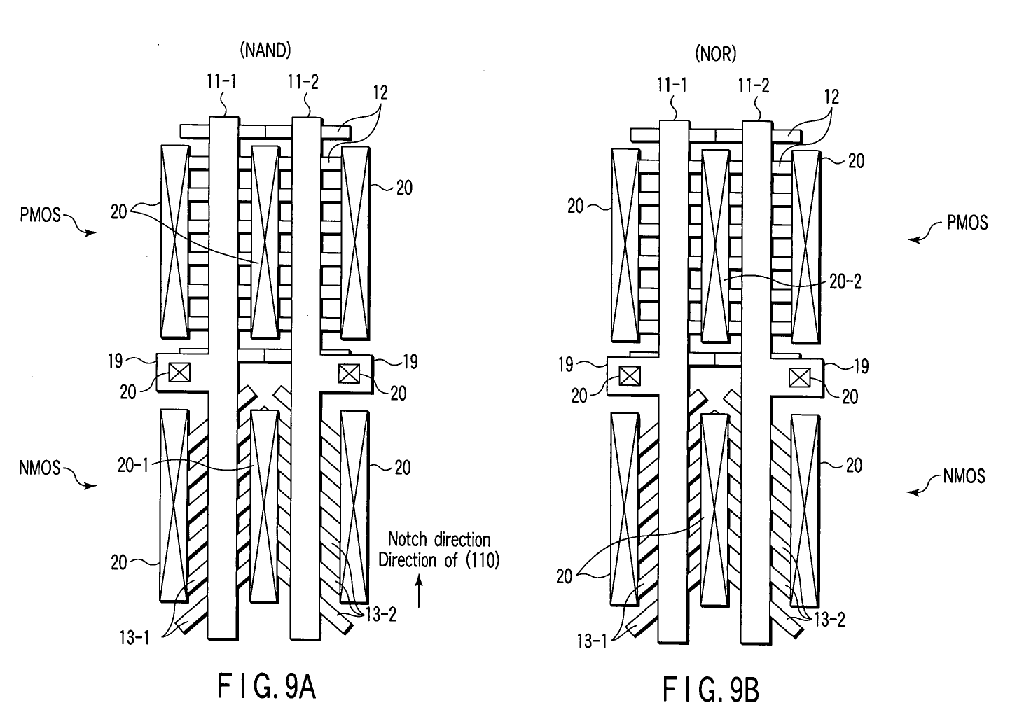

FIGS. 9A and 9B show a seventh embodiment of the present invention, i.e., a modification of the sixth embodiment shown in FIGS. 8A and 8B. In FIGS. 9A and 9B, the portions that are the same as those in the sixth embodiment are identified by the same reference numerals as those used in FIGS. 8A and 8B.

In the seventh embodiment, contacts are formed in regions where no contact is required. In other words, as shown in FIG. 8A, a contact need not be formed between the gate electrodes 11-1 and 11-2 of the NMOS-FinFET, and as shown in FIG. 8B, a contact need not be formed between the gate electrodes 11-1 and 11-2 of the PMOS-FinFET. However, according to the seventh embodiment, a contact 20-1 is formed between the gate electrodes 11-1 and 11-2 of the NMOS-FinFET as shown in FIG. 9A, and a contact 20-2 is formed between the gate electrodes 11-1 and 11-2 of the PMOS-FinFET as shown in FIG. 9B. These contacts 20-1 and 20-2 are not connected to a wire of the upper layer (not shown).

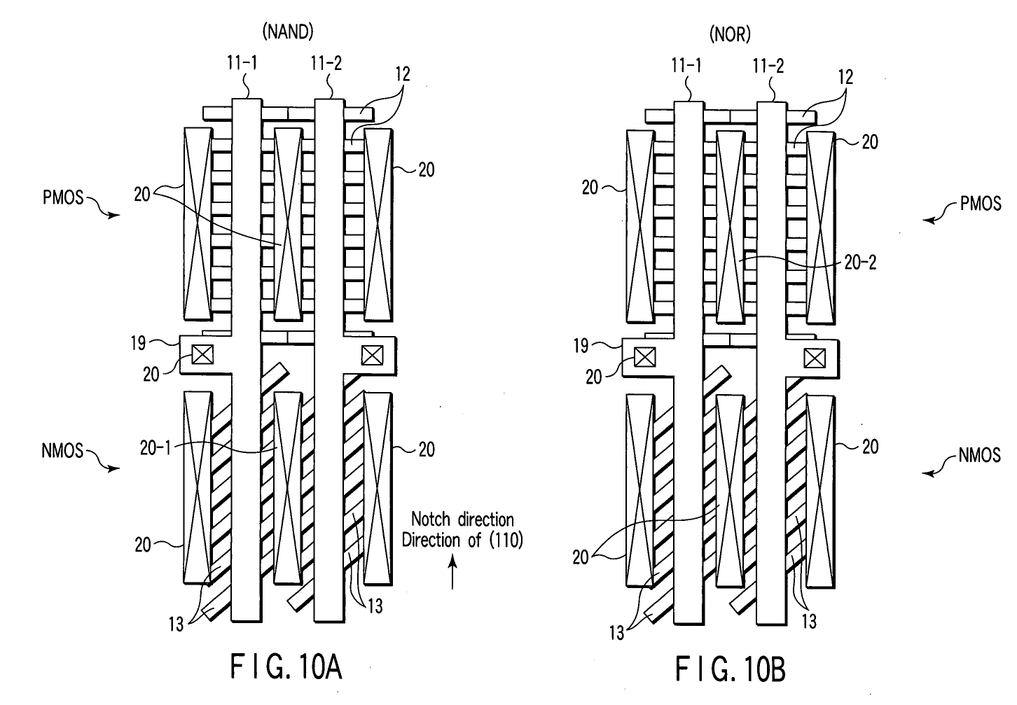

FIGS. 10A and 10B show a case in which the seventh embodiment is applied to FIGS. 4A and 4B. The portions that are the same as those shown in FIGS. 4A, 4B and 9A and 9B are identified by the same reference numerals as those used in these figures.

According to the seventh embodiment, the source/drain regions of all Fins are electrically connected by the contacts 20, 20-1 and 20-2. Therefore, the parasitic resistance in the source/drain regions can be reduced, and the device operation speed can be further increased.

Moreover, since the contacts are formed in the portions where no contact is required, the contacts can be arranged regularly. Therefore, the manufacturing process can be simplified.

### Eighth Embodiment

FIGS. 11-19 show a method for manufacturing a semiconductor device according to an eighth embodiment, in which the regions indicated by the broken lines A1 and A2 in FIG. 1 are shown.

Referring to FIG. 11, a bulk silicon substrate 21 is a wafer of the surface orientation (100), for example. An oxide film (not shown) of a thickness of about 5 nm is formed on the substrate 21. A silicon nitride film 22 of a thickness of about 100 nm is deposited on the oxide film. An amorphous silicon film of a thickness of about 120 nm is formed on the silicon nitride film 22. The amorphous silicon film is processed into dummy patterns 23-1 and 23-2. This process is performed by lithography using a laser source, such as KrF or ArF, and, for example, the Reactive Ion Etching (RIE). Then, a TEOS film of a thickness of about 30 nm is deposited on the overall surface, and the TEOS film is etched by the RIE, thereby forming mask patterns 24-1 and 24-2 on side surfaces of the dummy patterns 23-1 and 23-2.

Thereafter, the dummy patterns 23-1 and 23-2 are removed by the RIE or wet etching, as shown in FIG. 12. The positions of the mask patterns 24-1 and 24-2 thus formed correspond to the Fins 12 of the PMOS-FinFET and the Fins 13 of the NMOS-FinFET shown in FIG. 1. In other words, the mask patterns 24-1 are perpendicular to the gate electrode, which is formed later along the direction of (110). The mask patterns 24-2 corresponding to the Fins 13 of the NMOS-FinFET are inclined by 45 degrees relative to the gate electrode, which is formed later along the direction of (110).

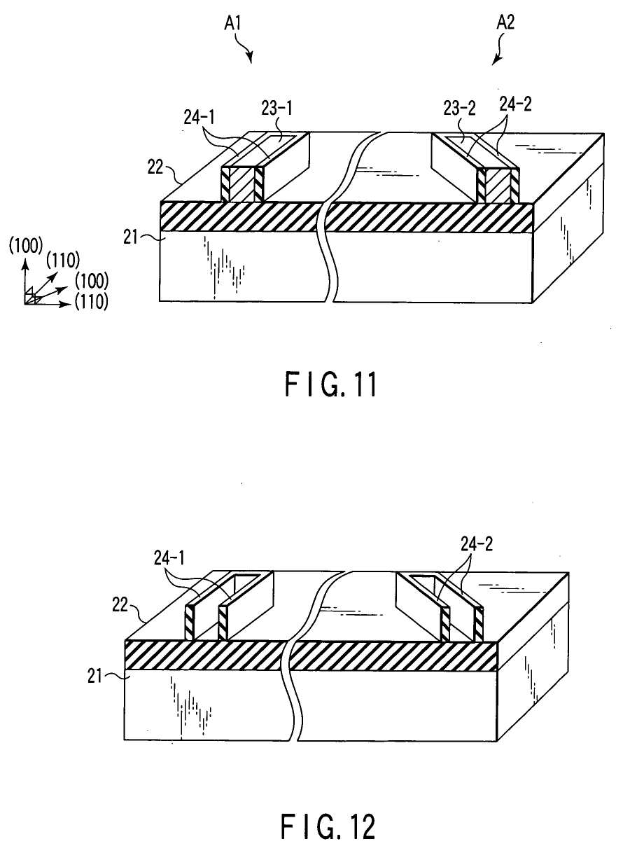

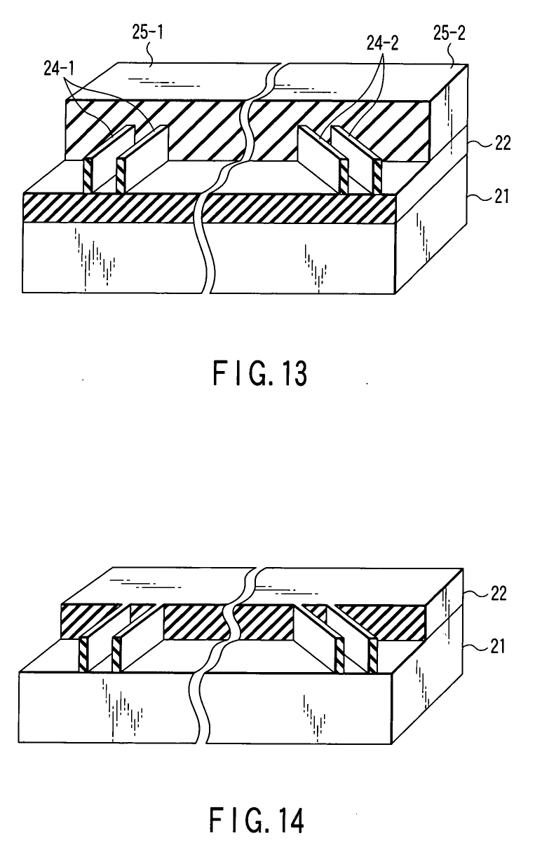

Then, as shown in FIG. 13, a resist pattern 25 is formed as follows. First, resist is applied to the overall surface, and resist patterns 25-1 and 25-2 corresponding to the element regions 16 and 18 (shown in FIG. 1), which electrically connect the adjacent Fins, are formed by lithography using a laser source, such as KrF or ArF.

Thereafter, as shown in FIG. 14, the silicon nitride film 22 is etched, using the resist patterns 25-1 and 25-2 and the mask patterns 24-1 and 24-2 as masks. Then, the resist patterns 25-1 and 25-2 and the mask patterns 24-1 and 24-2 are removed, thereby forming a pattern made of the silicon nitride film 22. If necessary, the pattern of the silicon nitride film 22 may be thinned by wet etching using, for example, hot phosphoric acid.

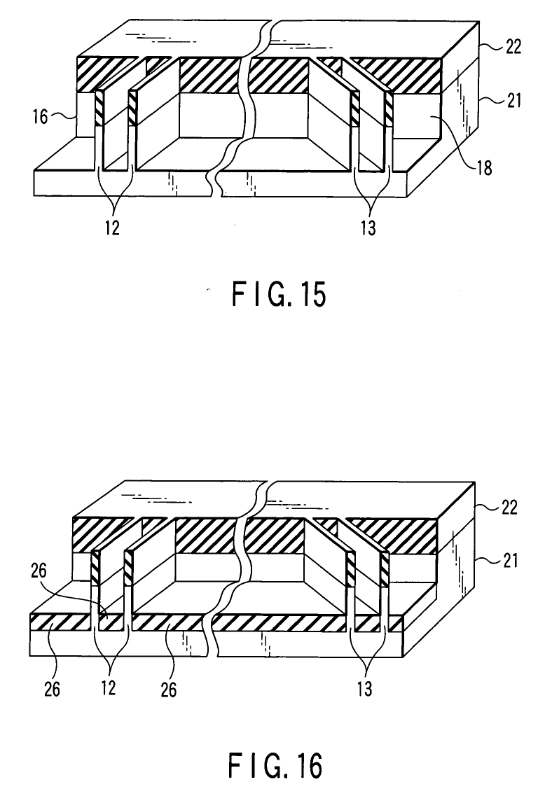

Then, as shown in FIG. 15, the silicon substrate 21 is etched to a depth of, for example, about 100 nm by the RIE using the pattern of the silicon nitride film 22 as a mask. This process forms the Fins 12 and 13, the element region 16 connecting the adjacent Fins 12 and the element region 18 connecting the adjacent Fins 13.

Thereafter, as shown in FIG. 16, a device isolation region 26 is formed on the substrate 21 as follows. First, a silicon oxide (SiO₂)-based film (e.g., high density plasma (HDP) or polysilazane), for device isolation, is deposited on the overall surface. The deposited film is flattened by the Chemical Mechanical Polishing (CMP). Further, the SiO₂-based film is etched back by the RIE, thereby forming the device isolation region 26 having a thickness of about 40 nm on the bottom of the groove. As a result, the Fins 12 and 13 having a height of about 60 nm are formed.

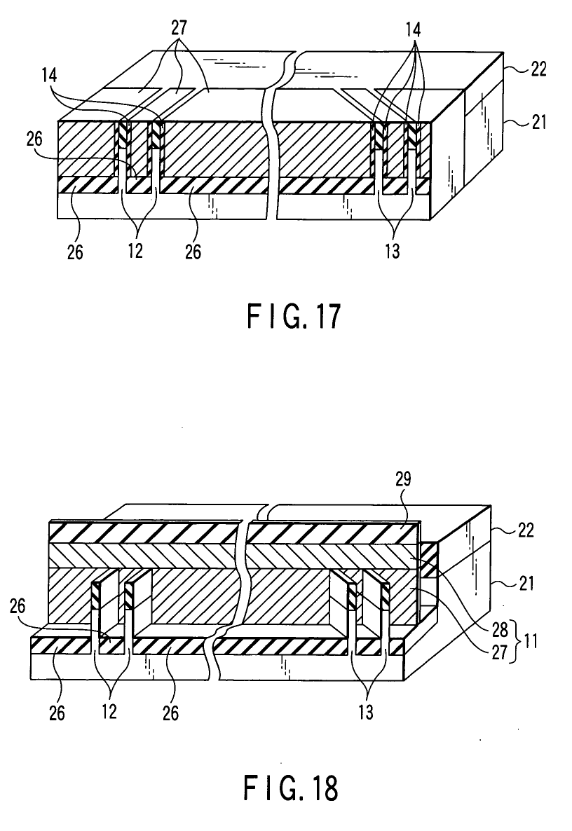

Thereafter, as shown in FIG. 17, gate insulating films 14, made of, for example, SiON or High-k film, are formed on the side surfaces of the Fins 12 and 13. Then, a first polysilicon film 27 as a gate electrode material is deposited on the resultant structure to a thickness of about 300 nm. The first polysilicon film 27 is flattened by the CMP using the silicon nitride film 22 as a stopper.

Next, the gate electrode 11 shown in FIG. 18 is formed as follows. First, a second polysilicon film 28 is deposited to a thickness of, for example, about 50 nm on the overall surface. A silicon nitride film 29 is deposited to a thickness of, for example, about 100 nm on the second polysilicon film 28. A resist pattern (not shown) corresponding to the gate electrode is formed on the silicon nitride film 29. The silicon nitride film 29 is processed, using the resist pattern as a mask, thereby forming a pattern made of the silicon nitride film 29. Using the pattern made of the silicon nitride film 29 as a mask, the first and second polysilicon films 27 and 28 are etched by the RIE. Thus, the gate electrode 11 shown in FIG. 18 is formed.

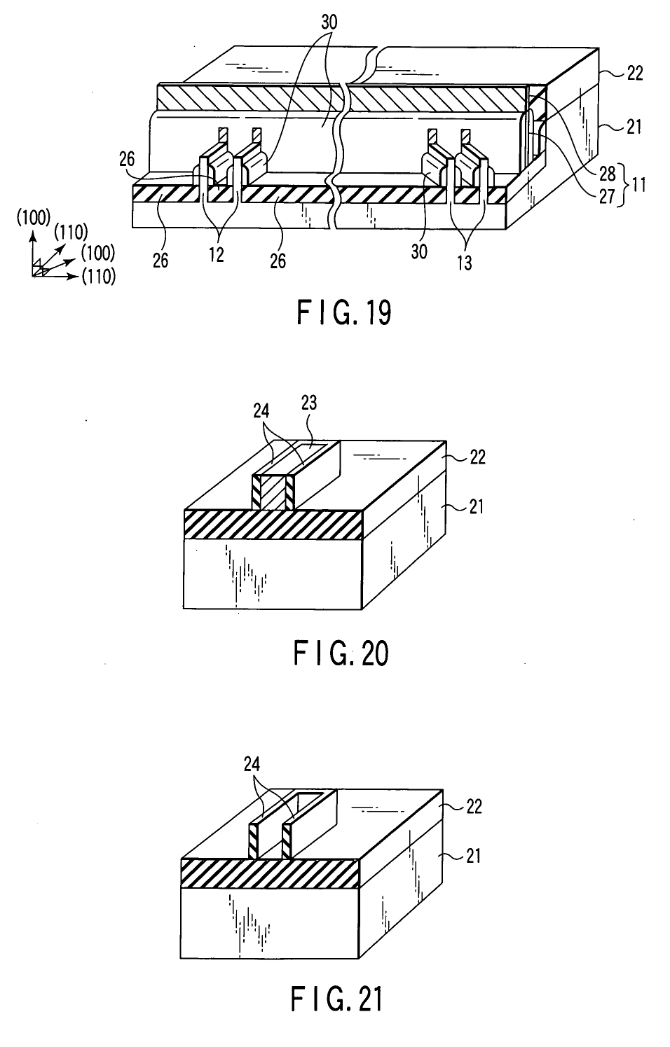

Thereafter, side wall insulating films 30 are formed on side walls of the gate electrode 11 and the first and second Fins 12 and 13, as shown in FIG. 19, in the following manner. First, a silicon nitride film and a TEOS film are sequentially deposited on the overall surface. The thickness of the stacked film is, for example, about 60 nm in total. Then, the stacked film is etched by the RIE so as to remain on the side walls of the gate electrode 11 and the Fins 12 and 13. At this time, the silicon nitride films 22 and 29 on the gate electrode 11 and the Fins 12 and 13 are simultaneously removed. Thus, the side wall insulating films 30 are formed on the side walls of the gate electrode 11 and the first and second Fins 12 and 13.

Thereafter, the same steps as in the conventional LSI manufacturing process are performed. More specifically, impurity ions are implanted into source/drain forming regions of the Fins 12, and forming source/drain regions through a salicide process using, for example, nickel silicide (not shown). Further, interlayer insulating films, contact holes, upper metal wires, passivation films, etc. are sequentially formed.

The doping into the side surfaces the Fins 12 and 13 is performed by using tilted ion implantation, plasma doping, spin ion implantation, etc.

According to the manufacturing method of the eighth embodiment, the PMOS-FinFET having the Fins 12 perpendicular to the gate electrode 11 and the NMOS-FinFET having the Fins 13 inclined relative to the gate electrode 11, as shown in FIG. 11, can be formed.

If a wafer, whose notch or orientation flat is shifted by 45 degrees, is used, it is possible to form the PMOS-FinFET having the Fins 12 inclined relative to the gate electrode 11 and the NMOS-FinFET having the Fins 13 perpendicular to the gate electrode 11, as shown in FIG. 3, in the same manufacturing method as in the eighth embodiment.

Moreover, according to the manufacturing method of the eighth embodiment, since there is no restriction in design, the CMOS inverters, in which the carrier mobility is high in both the PMOS-FinFET and the NMOS-FinFET, can be obtained by utilizing the conventional design property.

### Ninth Embodiment

FIGS. 20 to 28 relate to a ninth embodiment. FIGS. 20 to 26 show a method for forming the region indicated by the broken line B in FIG. 8B, and FIGS. 27 and 28 shows a method for forming the region indicated by the broken line C in FIG. 8B. Thus, the ninth embodiment relates to a method for forming a structure in which the adjacent Fins are connected to each other by a contact without forming a relatively large element region therebetween.

Referring to FIG. 20, a bulk silicon substrate 21 is, for example, a wafer of the surface orientation (100). An oxide film (not shown) of a thickness of about 5 nm is formed on the substrate 21. A silicon nitride film 22 of a thickness of about 100 nm is deposited on the oxide film. For example, an amorphous silicon film is formed on the silicon nitride film 22. The amorphous silicon film is processed into a dummy pattern 23 having a thickness of about 120 nm by lithography using a laser source, such as KrF or ArF, and, for example, the RIE. Then, a TEOS film of a thickness of about 30 nm is deposited on the resultant structure, and the TEOS film is etched by the RIE, thereby forming a mask pattern 24 on the side surfaces of the dummy pattern 23.

Thereafter, the dummy pattern 23 is removed by the RIE or wet etching, as shown in FIG. 21. The position of the mask pattern 24 thus formed corresponds to the Fin 12 of the PMOS-FinFET shown in FIG. 8B. In other words, the mask pattern 24 is perpendicular to the gate electrode, which is formed later along the direction of (110). The mask pattern (not shown) corresponding to the Fin 13 of the NMOS-FinFET is inclined by 45 degrees relative to the gate electrode, which is formed later along the direction of (110).

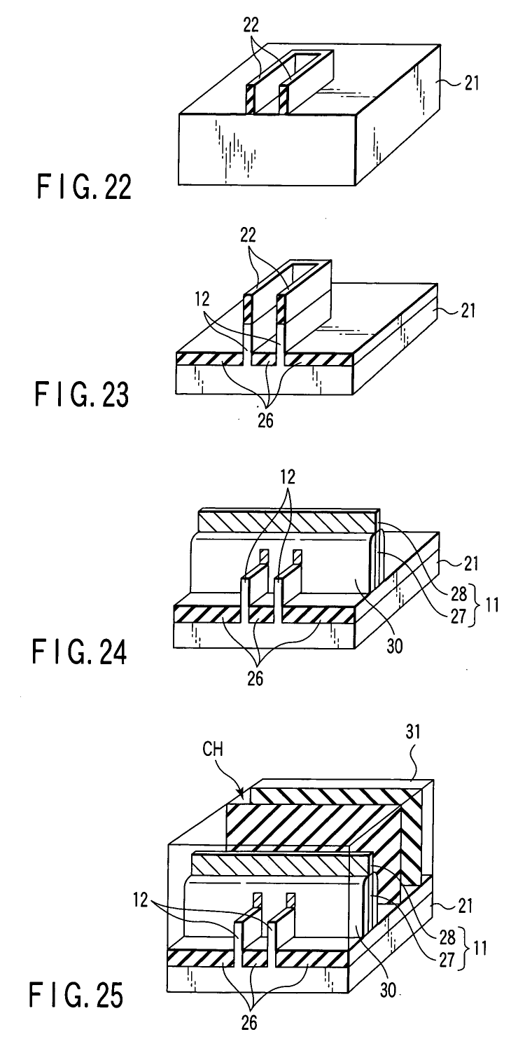

Thereafter, as shown in FIG. 22, the silicon nitride film 22 is etched, using the mask pattern 24 as a mask. Then, the mask pattern 24 is removed, thereby forming a pattern made of the silicon nitride film 22. If necessary, the pattern of the silicon nitride film 22 may be thinned by wet etching using, for example, hot phosphoric acid.

Then, as shown in FIG. 23, the silicon substrate 21 is etched to a depth of, for example, about 100 nm by the RIE using the pattern of the silicon nitride film 22 as a mask, thereby forming the Fin 12. Then, an device isolation region 26 is formed as follows. First, an SiO₂-based film (e.g., HDP or polysilazane) is deposited on the overall surface. The deposited SiO₂-based film is flattened by the CMP and etched back by the RIE. Thus, the SiO₂-based film is caused to remain on the bottom of the groove to a thickness of about 40 nm, thereby forming the device isolation region 26. As a result, the Fin 12 having a height of about 60 nm are formed.

Then, in the region indicated by the broken line B in FIG. 8B, the gate electrode 11 is formed in the same manner as in the eighth embodiment, as shown in FIG. 24. More specifically, gate oxide films (not shown), made of SiON or High-k film, are formed on the side surfaces of the Fin 12. Then, a first polysilicon film 27 as a gate electrode material is deposited on the overall surface to a thickness of about 300 nm. The first polysilicon film 27 is flattened by the CMP. Then, a second polysilicon film 28 is deposited to a thickness of about 50 nm on the overall surface, and subsequently a silicon nitride film (not shown) is deposited to a thickness of about 100 nm on the second polysilicon film 28. A resist pattern corresponding to the gate electrode is formed on the silicon nitride film. The silicon nitride film is processed, using the resist pattern as a mask, thereby forming a pattern made of the silicon nitride film. Using the pattern made of the silicon nitride film as a mask, the first and second polysilicon films 27 and 28 are etched by the RIE. Thus, the gate electrode 11 is formed. Thereafter, a silicon nitride film and a TEOS film are sequentially deposited on the overall surface. The thickness of the stacked film is, for example, about 60 nm in total. Then, the stacked film is etched by the RIE, thereby forming side wall insulating films 30, made of the stacked film of the silicon nitride film and the TEOS film, on the side walls of the gate electrode. At this time, the silicon nitride films on the gate electrode 11 and the Fin 12 are simultaneously removed.

Thereafter, the same steps as in the conventional LSI manufacturing process are performed. More specifically, impurity ions are implanted into source/drain forming regions of the Fin 12, and a salicide process using, for example, nickel silicide (not shown) is performed.

Further, as shown in FIG. 25 (the part indicated by the broken line C in FIG. 8B is shown in FIG. 27), an interlayer insulating film 31 is deposited on the overall surface, and then flattened. Thereafter, a contact hole CH is formed in the interlayer insulating film 31.

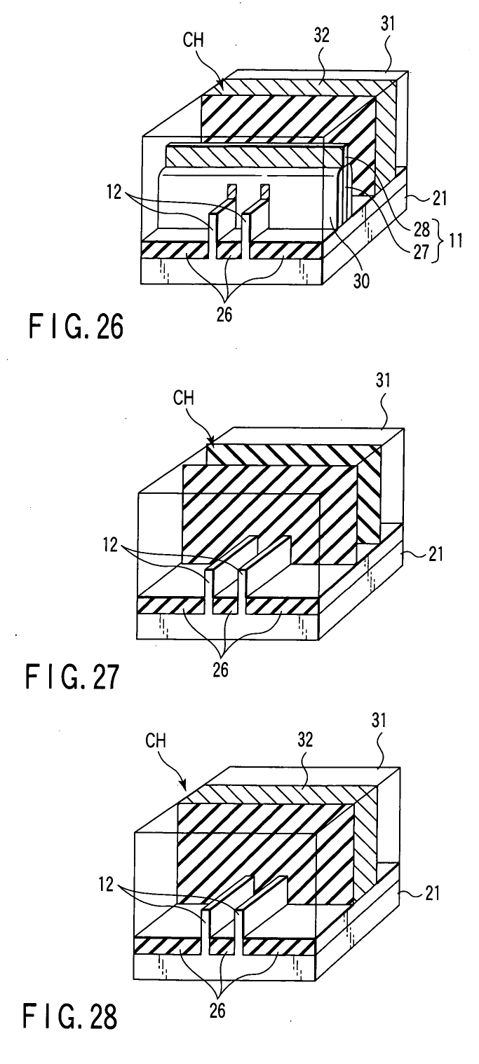

Thereafter, as shown in FIG. 26 (the part indicated by the broken line C in FIG. 8B is shown in FIG. 28), for example, the contact hole CH is filled with W/TiN/Ti, with the result that a contact 32 is formed. The contact 32 electrically connects the adjacent Fins 12. Then, an upper metal wire, a passivation film, etc. are sequentially formed.

A description of steps for manufacturing an NMOS-FinFET is omitted, but an NMOS-FinFET can be manufactured in the same manner as in manufacturing the PMOS-FinFET described above.

According to the method of the ninth embodiment, a PMOS-FinFET and an NMOS-FinFET, in which a plurality of adjacent Fins 12 or Fins 13 are connected by a contact 20 as shown in FIGS. 8A and 8B, can be manufactured.

If a wafer, whose notch or orientation flat is shifted by 45 degrees, is used, it is possible to form the PMOS-FinFET having the Fins inclined relative to the gate electrode 11 and the NMOS-FinFET having the Fins perpendicular to the gate electrode 11, as shown in FIG. 3, in the same manufacturing method as in the ninth embodiment.

Moreover, according to the manufacturing method of the ninth embodiment, since there is no restriction in design, the CMOS inverters, in which the carrier mobility is high in both the PMOS-FinFET and the NMOS-FinFET, can be obtained by utilizing the conventional design property.

### Tenth Embodiment

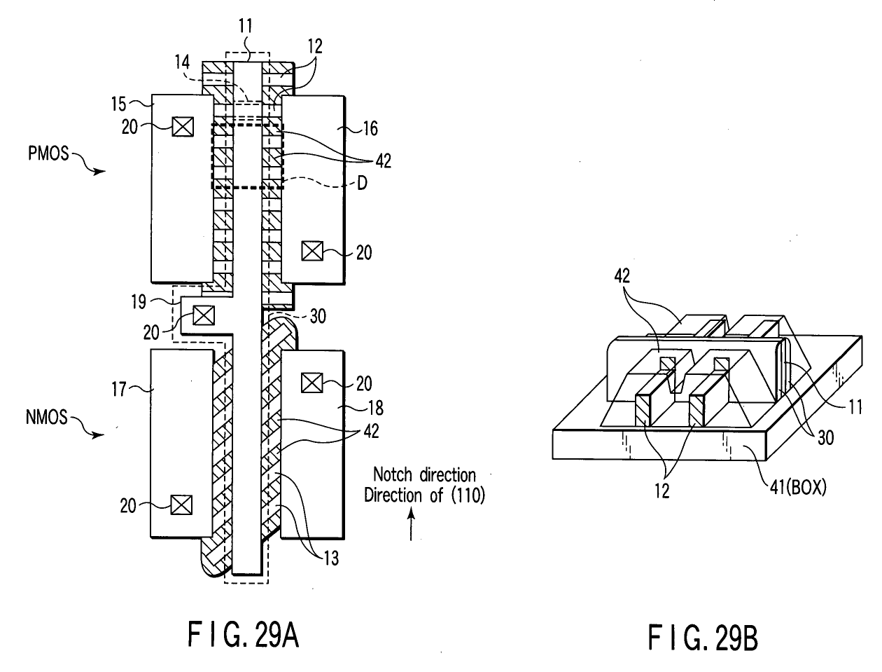

FIGS. 29A and 29B show a tenth embodiment. In FIGS. 29A and 29B, the portions that are the same as those shown in FIGS. 1 and 19 are identified by the same reference numerals as those used in these figures.

As shown in FIGS. 29A and 29B, in the tenth embodiment, the adjacent Fins 12 are connected to one another by an epitaxial layer 42. The epitaxial layer 42 is formed as follows. In the tenth embodiment, the manufacturing steps from the start to the forming of the side wall insulating films 30 on the side walls of the gate electrode 11 and the side walls of the Fins 12 are the same as those in the eighth embodiment shown in FIGS. 11 to 19.

After the side wall insulating films 30 are formed on the side walls of the gate electrode 11 and the side walls of the Fins 12 and 13, as shown in FIG. 19, the side wall insulating films 30 on the Fins 12 and 13 are removed. Then, as shown in FIGS. 29A and 29B, the Fins 12, which function as source/drain regions, are epitaxially grown, so that the width and height of each Fin 12 are increased. The adjacent Fins 12 are connected to one another by the epitaxial layer 42 formed by this epitaxial growth. As well as the Fins 12, the adjacent Fins 13 in the NMOS-FinFET (not shown) are also connected to one another by the epitaxial layer 42.

In the tenth embodiment, the Fins 12 and 13, which serve as source/drain regions, are electrically connected to one another by the epitaxial layer 42. Therefore, the parasitic resistance of the source/drain regions can be reduced, and the device operation speed can be increased.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a gate electrode, which is arranged in a direction parallel or perpendicular to a specified crystal orientation of a substrate;
a first transistor of a first conductivity type, having a first active region which is arranged in a direction perpendicular to the gate electrode; and
a second transistor of a second conductivity type, having a second active region which is inclined relative to the gate electrode.

2. The device according to claim 1, wherein the specified crystal orientation is <110>, the first transistor of the first conductivity type is a p-channel MOS transistor, and the second transistor of the second conductivity type is an n-channel MOS transistor.

3. The device according to claim 1, wherein the specified crystal orientation is <100>, the first transistor of the first conductivity type is an n-channel MOS transistor, and the second transistor of the second conductivity type is a p-channel MOS transistor.

4. The device according to claim 1, wherein the second active region is inclined by 45 degrees relative to the gate electrode.

5. The device according to claim 1, wherein the first active region and the second active region are inclined by 45 degrees relative to each other.

6. The device according to claim 1, wherein the first active region has a plurality of first Fins, and the second active region has a plurality of second Fins, the plurality of first Fins being electrically connected to one another, and the plurality of second Fins being electrically connected to one another.

7. The device according to claim 6, wherein the plurality of first Fins are electrically connected by a first epitaxial layer, and the plurality of second Fins are electrically connected by a second epitaxial layer.

8. A semiconductor device comprising:
a first gate electrode and a second gate electrode, which are arranged in a direction parallel or perpendicular to a specified crystal orientation of a substrate;
a first transistor and a second transistor of a first conductivity type, respectively having a first active region and a second active region which are arranged in a direction perpendicular to the first gate electrode and the second gate electrode; and
a third transistor and a fourth transistor of a second conductivity type, respectively having a third active region and a fourth active region which are inclined relative to the first gate electrode and the second gate electrode.

9. The device according to claim 8, wherein the specified crystal orientation is <110>, the first transistor and the second transistor of the first conductivity type are p-channel MOS transistors, and the third transistor and the fourth transistor of the second conductivity type are n-channel MOS transistors.

10. The device according to claim 8, wherein the specified crystal orientation is <100>, the first transistor and the second transistor of the first conductivity type are n-channel MOS transistors, and the third transistor and the fourth transistor of the second conductivity type are p-channel MOS transistors.

11. The device according to claim 8, wherein the third active region and the fourth active region are inclined by 45 degrees relative to the first gate electrode and the second gate electrode, respectively.

12. The device according to claim 8, wherein the first active region and the second active region are inclined by 45 degrees relative to the third active region and the fourth active region, respectively.

13. The device according to claim 8, wherein the third active region is inclined by 45 degrees relative to the first gate electrode, and the fourth active region is inclined by 315 degrees relative to the second gate electrode.

14. The device according to claim 13, wherein the third active region and the fourth active region are connected to each other.

15. The device according to claim 8, wherein the first active region has a plurality of first Fins, the second active region has a plurality of second Fins, the third active region has a plurality of third Fins, the fourth active region has a plurality of fourth Fins, the plurality of first Fins being electrically connected to one another, the plurality of second Fins being electrically connected to one another, the plurality of third Fins being connected to one another and the plurality of fourth Fins being connected to one another.

16. The device according to claim 15, further comprising a connecting portion, which connects the plurality of first Fins and the plurality of second Fins located between the first gate electrode and the second gate electrode.

17. The device according to claim 16, wherein a distance between the first gate electrode and the second gate electrode in a region where the contact portion is not formed between the first gate electrode and the second gate electrode is smaller than a distance between the first gate electrode and the second gate electrode in a region where the contact portion is formed.

18. A method for manufacturing a semiconductor device comprising:
forming a first active region which has a side surface arranged in a direction parallel or perpendicular to a specified crystal orientation of a substrate, and a second active region which has a side surface inclined relative to the specified crystal orientation of the substrate;
forming a first insulating film which covers the first active region and the second active region;
forming a first conductive film on the first insulating film;
forming a mask, which is parallel or perpendicular to the specified crystal orientation of the substrate, perpendicular to the first active region, and inclined relative to the second active region; and
etching the first conductive film, using the mask, thereby forming a gate electrode.

19. The method according to claim 18, wherein the second active region is inclined by 45 degrees relative to the specified crystal orientation of the substrate.

20. The method according to claim 18, wherein the first active region has a plurality of first Fins, the second active region has a plurality of second Fins, the plurality of first Fins being electrically connected to one another by a first epitaxial layer, and the plurality of second Fins being electrically connected to one another by a second epitaxial layer.
